(19) United States
(12) Patent Application Publication
(10) Pub. No.: US 2026/0068305 A1
(43) Pub. Date: Mar. 5, 2026

(54) BACKSIDE PLACEHOLDER MODIFICATION WITH NARROW ACTIVE REGION AND BACKSIDE CONTACT

(71) Applicant: INTERNATIONAL BUSINESS MACHINES CORPORATION, ARMONK, NY (US)

(72) Inventors: Darsith Jayachandran, Menands, NY (US); Ruilong Xie, Niskayuna, NY (US); Tao Li, Slingerlands, NY (US); Kisik Choi, Watervliet, NY (US)

(21) Appl. No.: 18/818,385

(22) Filed: Aug. 28, 2024

(51) Int. Cl. H01L 27/092; H01L 29/06; H01L 29/417; H01L 29/423; H01L 29/66; H01L 29/775; H01L 29/786

(52) U.S. Cl. CPC H10D 84/856; H10D 30/6729; H10D 62/116; H10D 30/014; H10D 30/43; H10D 30/6735; H10D 30/6757; H10D 62/121

(57) ABSTRACT

A microelectronic structure that includes a first nanosheet FET, wherein the first nanosheet FET has an active region having a first width, wherein the first width is measured in parallel with a gate direction, wherein the first nanosheet FET includes a first placeholder, and a first source/drain, wherein first placeholder is located on a backside of the first source/drain. A second nanosheet FET, wherein the second nanosheet FET has an active region having a second width, wherein the second width is measured in parallel with the gate direction, wherein the second width is smaller than the first width, wherein the second nanosheet FET includes a second placeholder, and a second source/drain, wherein second placeholder is located on a backside of the second source/drain.

### BACKGROUND

The present invention generally relates to the field of microelectronics, and more particularly to the contact area for a backside contact.

Establishing the connection between the two or more metal layers within a microelectronic structure often includes various processes, such as, but not limited to removal/etching and/or patterning/lithography. During these processes, the alignments of the via connections may vary as a result of any number of inconsistencies during these processes, such as, but not limited to, inconsistencies in placeholder depth and varying sizes of active regions.

### BRIEF SUMMARY

Additional aspects and/or advantages will be set forth in part in the description which follows and, in part, will be apparent from the description, or may be learned by practice of the invention.

A microelectronic structure that includes a first nanosheet FET, wherein the first nanosheet FET has an active region having a first width, wherein the first width is measured in parallel with a gate direction, wherein the first nanosheet FET includes a first placeholder, and a first source/drain, wherein first placeholder is located on a backside of the first source/drain, wherein the first placeholder has a first depth, wherein the first depth as measured from the backside of the first source/drain towards the backside of the first nanosheet FET. A second nanosheet FET, wherein the second nanosheet FET has an active region having a second width, wherein the second width is measured in parallel with the gate direction, wherein the second width is smaller than the first width, wherein the second nanosheet FET includes a second placeholder, and a second source/drain, wherein second placeholder is located on a backside of the second source/drain, wherein the second placeholder has a second depth, wherein the second depth as measured from the backside of the second source/drain towards the backside of the second nanosheet FET.

A microelectronic structure that includes a first nanosheet FET, wherein the first nanosheet FET has an active region having a first width, wherein the first width is measured in parallel with a gate direction, wherein the first nanosheet FET includes a first placeholder, a first backside contact, a first source/drain, and a second source/drain, wherein first placeholder is located on a backside of the first source/drain, wherein the first placeholder has a first depth, wherein the first depth as measured from the backside of the first source/drain towards the backside of the first nanosheet FET, and wherein the first backside contact is located on a backside of the second source/drain. A second nanosheet FET, wherein the second nanosheet FET has an active region having a second width, wherein the second width is measured in parallel with the gate direction, wherein the second width is smaller than the first width, wherein the second nanosheet FET includes a second placeholder, a second backside contact, a third source/drain, and a fourth source/drain, wherein second placeholder is located on a backside of the third source/drain, wherein the second placeholder has a second depth, wherein the second depth as measured from the backside of the third source/drain towards the backside of the second nanosheet FET, and wherein the second backside contact is located on a backside of the fourth source/drain.

A method comprising forming a first nanosheet FET, wherein the first nanosheet FET has an active region having a first width, wherein the first width is measured in parallel with a gate direction, wherein the first nanosheet FET includes a first placeholder, and a first source/drain, wherein first placeholder is located on a backside of the first source/drain, wherein the first placeholder has a first depth, wherein the first depth as measured from the backside of the first source/drain towards the backside of the first nanosheet FET. Forming second nanosheet FET, wherein the second nanosheet FET has an active region having a second width, wherein the second width is measured in parallel with the gate direction, wherein the second width is smaller than the first width, wherein the second nanosheet FET includes a second placeholder, and a second source/drain, wherein second placeholder is located on a backside of the second source/drain, wherein the second placeholder has a second depth, wherein the second depth as measured from the backside of the second source/drain towards the backside of the second nanosheet FET.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the microelectronic structure, in accordance with the embodiment of the present invention.

FIG. 2A illustrates a cross-section X1 of the first width active region scenario of the microelectronic structure after frontside processing, in accordance with the embodiment of the present invention.

FIG. 2B illustrates a cross-section X2 of the second width active region scenario of the microelectronic structure after frontside processing, in accordance with the embodiment of the present invention.

FIG. 3A illustrates the cross-section X1 of the first width active region scenario of the microelectronic structure after flipping of the device over for backside processing and after first substrate removal, in accordance with the embodiment of the present invention.

FIG. 3B illustrates the cross-section X2 of the second width active region scenario of the microelectronic structure after flipping of the device over for backside processing and after first substrate removal, in accordance with the embodiment of the present invention.

FIG. 4A illustrates the cross-section X1 of the first width active region scenario of the microelectronic structure after the removal of a stop layer and partial etching of the second substrate exposing a bottom portion of the placeholders, in accordance with the embodiment of the present invention.

FIG. 4B illustrates the cross-section X2 of the second width active region scenario of the microelectronic structure after the removal of the stop layer and partial etching of the second, in accordance with the embodiment of the present invention.

FIG. 5A illustrates the cross-section X1 of the first width active region scenario of the microelectronic structure after removal of the exposed bottom portion of the placeholders and a portion of the unexposed portion of the placeholders, in accordance with the embodiment of the present invention.

FIG. 5B illustrates the cross-section X2 of the second width active region scenario of the microelectronic structure in the same state of the backside processing as FIG. 4B, after the removal of the stop layer and partial etching of the second substrate, in accordance with the embodiment of the present invention.

FIG. 6A illustrates the cross-section X1 of the first width active region scenario of the microelectronic structure after the removal of the remaining second substrate exposing the placeholders, in accordance with the embodiment of the present invention.

FIG. 6B illustrates the cross-section X2 of the second width active region scenario of the microelectronic structure after the removal of the remaining second substrate exposing the placeholders, in accordance with the embodiment of the present invention.

FIG. 7A illustrates the cross-section X1 of the first width active region scenario of the microelectronic structure after the formation of the backside interlayer dielectric layer, in accordance with the embodiment of the present invention.

FIG. 7B illustrates the cross-section X2 of the second width active region scenario of the microelectronic structure after the formation of the backside interlayer dielectric layer, in accordance with the embodiment of the present invention.

FIG. 8A illustrates the cross-section X1 of the first width active region scenario of the microelectronic structure after patterning of the backside interlayer dielectric layer forming a trench in contact with a bottom surface of one of the placeholders, in accordance with the embodiment of the present invention.

FIG. 8B illustrates the cross-section X2 of the second width active region scenario of the microelectronic structure after patterning of the backside interlayer dielectric layer and removing a portion of one of the placeholders such that a trench is formed in contact with a bottom surface of one of the placeholders, in accordance with the embodiment of the present invention.

FIG. 9A illustrates the cross-section X1 of the first width active region scenario of the microelectronic structure after the removal of the remaining portion of one of the placeholders and the formation of the backside contact with the bottom surface of a first source/drain, in accordance with the embodiment of the present invention.

FIG. 9B illustrates the cross-section X2 of the second width active region scenario of the microelectronic structure after the removal of the remaining portion of one of the placeholders and the formation of the backside contact with the bottom surface of a first source/drain, in accordance with the embodiment of the present invention.

FIG. 10A illustrates the cross-section X1 of the first width active region scenario of the microelectronic structure after the formation of an additional backside interconnect layer, in accordance with the embodiment of the present invention.

FIG. 10B illustrates the cross-section X2 of the second width active region scenario of the microelectronic structure after the formation of an additional backside interconnect layer, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming transistors within a microelectronic structure with varying placeholder depth and varying sizes of active regions.

Establishing the connection between the two or more metal layers within a microelectronic structure often includes various processes, such as, but not limited to removal/etching and/or patterning/lithography. During these processes, the alignments of the via connections may vary as a result of any number of inconsistencies during these processes, such as, but not limited to, inconsistencies in placeholder depth and varying sizes of active regions. The differences in active region width and placeholder depth may cause a short to an adjacent active region placeholder in cases of misalignment. The present invention addresses the challenges in transistor formation forming uniform placeholders between various sized active regions for a robust direct backside contact formation process.

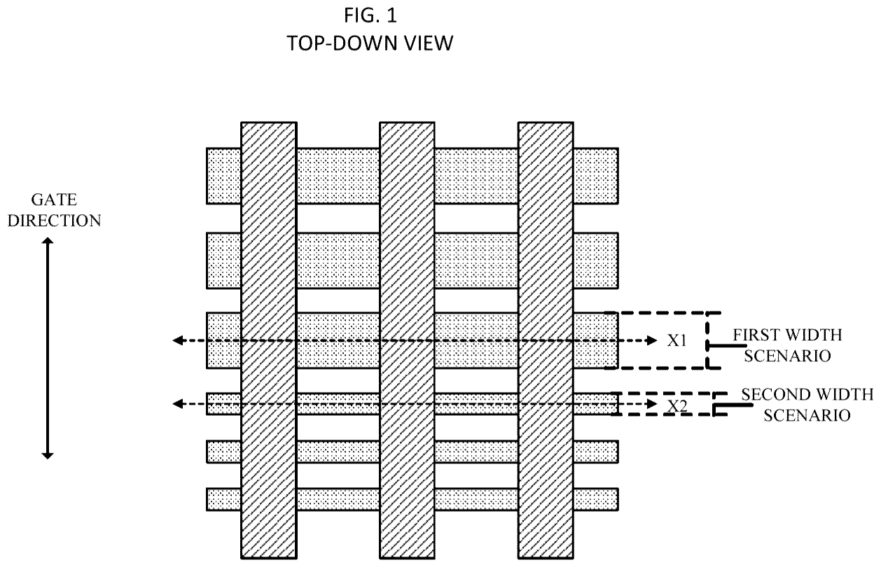

FIG. 1 illustrates a top-down view of multiple microelectronic structures, in accordance with the embodiment of the present invention. The cross-sections X1 and X2 extend through the active region of the microelectronic structure and are perpendicular to the gate direction. The cross-section X1 is of the first width of the active region scenario and the cross-section X2 is of the second width of the active region scenario. The first width of cross-section X1 may be greater than the second width of cross-section X2. The first width scenario may have an active region greater than 15 nanometers (nm). The second width scenario may have an active region less than or equal to 15 nm.

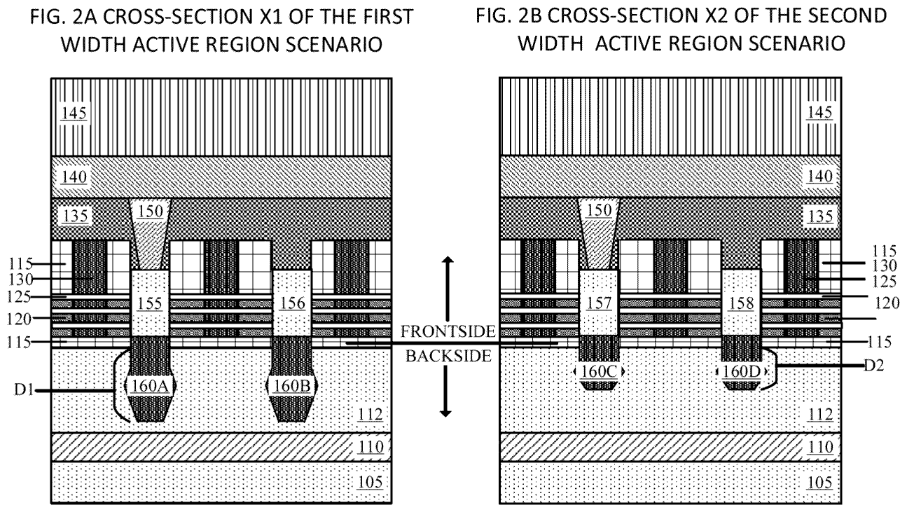

Referring now to FIG. 2, multiple microelectronic electronic structures are shown illustrating the processing stage after the completion of the frontside processing of the microelectronic structure. FIG. 2 illustrates the processing stage prior to the microelectronic structures being flipped over for backside processing using the carrier wafer 145. Although the flipping of the microelectronic structures is not shown, the directions of the microelectronic structures are indicated in each of the FIGS. 2-10.

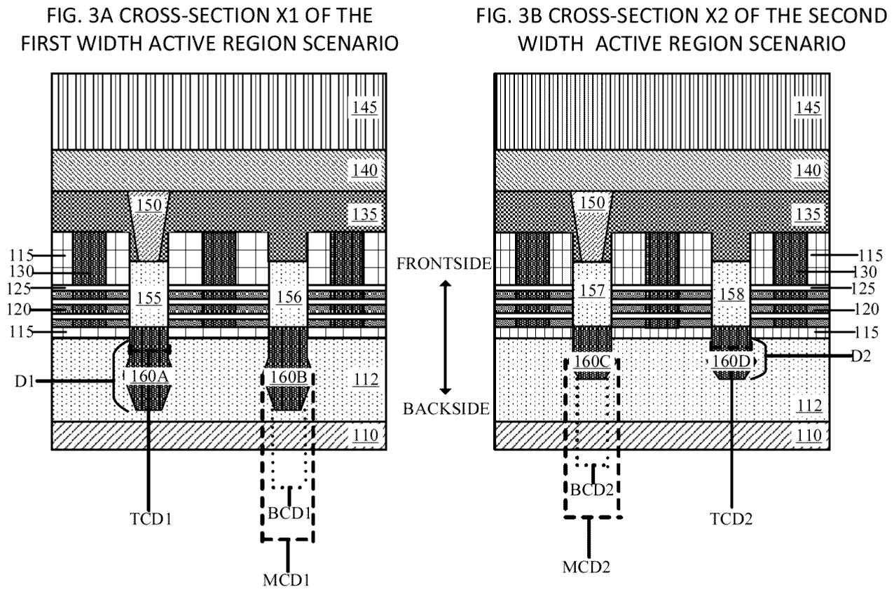

FIG. 2A illustrates a cross-section X1 of the first width active region scenario after frontside processing of the first nanosheet FET. FIG. 2A illustrates the microelectronic structure that includes a first substrate 105, an etch stop 110, a second substrate 112, a bottom dielectric isolation layer 115, inner spacer 120, channel layers 125, gate material 130, frontside interlayer dielectric layer 135, back-end-of-line (BEOL) layer 140, carrier wafer 145, frontside contact 150, source/drain 155, source/drain 156, placeholder 160A, and placeholder 160B. The depth of placeholders 160A and 160B is emphasized by brackets D1, as will be explained in relation to FIG. 2B the depth of placeholders 160A and 160B is greater than the depth of placeholders 160C and 160D emphasized by brackets D2. The dimensions of placeholders 160A, 160B, 160C, and 160D will be described in detail in FIG. 3.

FIG. 2B illustrates a cross-section X2 of the second width active region scenario after frontside processing of the second nanosheet FET. FIG. 2B illustrates the microelectronic structure that includes a first substrate 105, an etch stop 110, a second substrate 112, a bottom dielectric isolation layer 115, inner spacer 120, channel layers 125, gate material 130, frontside interlayer dielectric layer 135, back-end-of-line (BEOL) layer 140, carrier wafer 145, frontside contact 150, source/drain 157, source/drain 158, placeholder 160C, and placeholder 160D. The depth of placeholders 160C and 160D is emphasized by brackets D2, the depth of placeholders 160C and 160D is less than the depth of the placeholders 160A and 160B of FIG. 2A as emphasized by brackets D1. The dimensions of placeholders 160A, 160B, 160C, and 160D will be described in detail in FIG. 3.

The first substrate 105 and the second substrate 112 can be, for example, a material including, but not necessarily limited to, silicon (Si), silicon germanium (SiGe), Si:C (carbon doped silicon), carbon doped silicon germanium (SiGe: C), III-V, II-V compound semiconductor or another like semiconductor. In addition, multiple layers of the semiconductor materials can be used as the semiconductor material of the first substrate 105 and the second substrate 112. In some embodiments, the first substrate 105 and the second substrate 112 includes both semiconductor materials and dielectric materials. The first substrate 105 and the second substrate 112 of the microelectronic structures may also comprise an organic semiconductor or a layered semiconductor such as, for example, Si/SiGe, a silicon-on-insulator or a SiGe-on-insulator. A portion or the entire first substrate 105 and the second substrate 112 of the microelectronic structures may also be comprised of an amorphous, polycrystalline, or monocrystalline. The first substrate 105 and the second substrate 112 of the microelectronic structures may be doped, undoped or contain doped regions and undoped regions therein. The placeholders 160A, 160B, 160C, and 160D may also be comprised of SiGe amongst any of the other materials detailed above.

The sources/drains, including, but not limited to including source/drain 155, source/drain 156, source/drain 157, source/drain 158 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

Gate material 130 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

FIGS. 3-10 illustrate the processing stage after flipping the microelectronic structure over for backside processing. Carrier wafer 145 allows for the microelectronic structure (logic device, or logic device with a passive device) to be flipped over for backside processing, i.e., flipping over the microelectronic structure exposes the backside region of the device. FIG. 2 illustrates the frontside processing of the microelectronic structure and FIGS. 3-10 illustrate the backside processing of the microelectronic structure.

FIG. 3A illustrates the cross-section X1 of the first width active region scenario of the microelectronic structure after flipping of the device over for backside processing and after first substrate 105 removal stopping at the etch stop layer 110. Although the flipping of the microelectronic structure from FIG. 2A to FIG. 3A is not shown, the directions of the microelectronic structures are indicated in each of the FIGS. 2-10.

FIG. 3A illustrates the microelectronic structure that includes the etch stop 110, the second substrate 112, the bottom dielectric isolation layer 115, the inner spacer 120, the channel layers 125, the gate material 130, the frontside interlayer dielectric layer 135, the BEOL layer 140, the carrier wafer 145, frontside contact 150, the source/drain 155, the source/drain 156, the placeholder 160A, and the placeholder 160B. The depth of the placeholders 160A and 160B is emphasized by brackets D1. The depth D1 of placeholders 160A and 160B is deeper in comparison to the depth D2 of placeholders 160C and 160D of FIG. 3B which illustrates the cross-section X2 of the second width in the active region scenario of the microelectronic structure.

FIG. 3A further illustrates the dimensions of placeholders 160A and 160B. The dimensions of the placeholders 160A and 160B include at least a bottom critical dimension (BCD), a middle critical dimension (MCD), and a top critical dimension (TCD). The width of the BCD of placeholders 160A and 160B is emphasized by brackets BCD1 on placeholder 160B. The width of the MCD of placeholders 160A and 160B is emphasized by brackets MCD1 on placeholder 160B. The width of the TCD of placeholders 160A and 160B is emphasized by brackets TCD1 on placeholder 160A. The width of the MCD of placeholders 160A and 160B is greater than the BCD and TCD of placeholders 160A and 160B, as emphasized by brackets BCD1, MCD1, and TCD1. The shape/dimensions of placeholders 160A and 160B are different from the shape/dimensions of placeholders 160C and 160D illustrated in FIG. 3B.

FIG. 3B illustrates the cross-section X2 of the second width active region scenario of the microelectronic structure after flipping of the device over for backside processing and after first substrate 105 removal stopping at the etch stop layer 110. Although the flipping of the microelectronic structure from FIG. 2B to FIG. 3B is not shown, the directions of the microelectronic structures are indicated in each of the FIGS. 2-10.

FIG. 3B illustrates the microelectronic structure that includes the etch stop 110, the second substrate 112, the bottom dielectric isolation layer 115, the inner spacer 120, the channel layers 125, the gate material 130, the frontside interlayer dielectric layer 135, the BEOL layer 140, the carrier wafer 145, frontside contact 150, the source/drain 157, the source/drain 158, the placeholder 160C, and the placeholder 160D. The depth of the placeholders 160C and 160D is emphasized by brackets D2. The depth D2 of placeholders 160C and 160D is shallower in comparison to the depth D1 of placeholders 160A and 160B of FIG. 3A which illustrates the cross-section X1 of the first width in the active region scenario of the microelectronic structure.

FIG. 3B further illustrates the dimensions of placeholders 160B and 160C. The dimensions of the placeholders 160B and 160C include at least a bottom critical dimension (BCD), a middle critical dimension (MCD), and a top critical dimension (TCD). The width of the BCD of placeholders 160C and 160D is emphasized by brackets BCD2 on placeholder 160C. The width of the MCD of placeholders 160C and 160D is emphasized by brackets MCD2 on placeholder 160C. The width of the TCD of placeholders 160C and 160D is emphasized by brackets TCD2 on placeholder 160D. The shape/dimensions of placeholders 160C and 160D are different from the shape/dimensions of placeholders 160A and 160B illustrated in FIG. 3A.

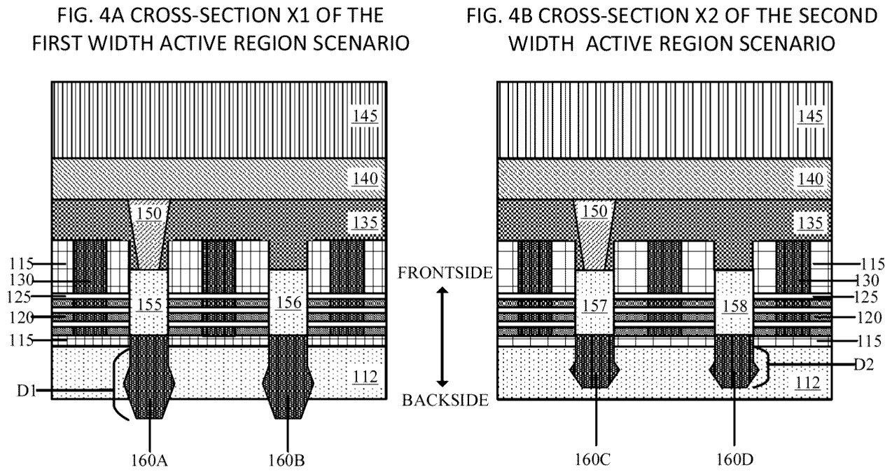

FIG. 4A illustrates the cross-section X1 of the first width active region scenario of the microelectronic structure after the removal of the etch stop layer 110 and partial etching of the second substrate 112 exposing a bottom portion of the placeholders 160A and 160B. The removal of the etch stop layer 110 and partial etching of the second substrate 112 in the cross-section X1 of the first width active region scenario exposes the bottom portion of placeholders 160A and 160B due to the depth D1 of placeholders 160A and 160B.

FIG. 4B illustrates the cross-section X2 of the second width active region scenario of the microelectronic structure after the removal of the etch stop layer 110 and partial etching of the second substrate 112. The removal of the etch stop layer 110 and partial etching of the second substrate 112 in the cross-section X2 of the second width active region scenario does not expose the bottom portion of placeholders 160C and 160D due to the depth D2 of placeholders 160C and 160D.

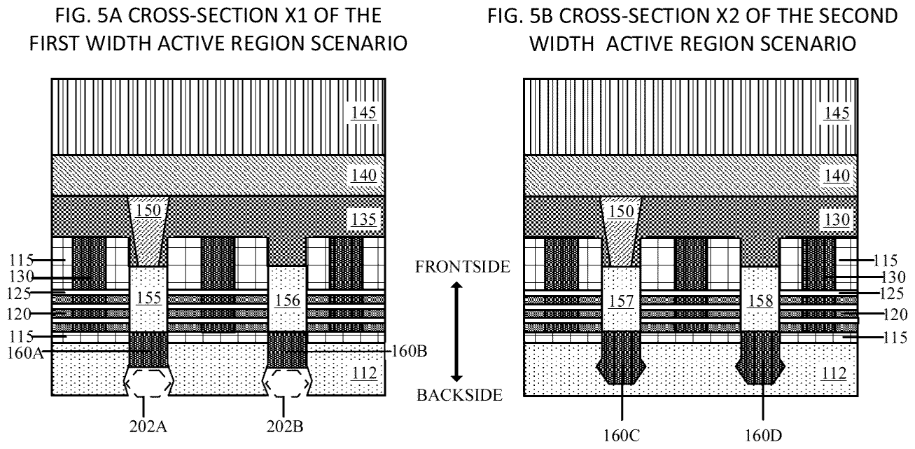

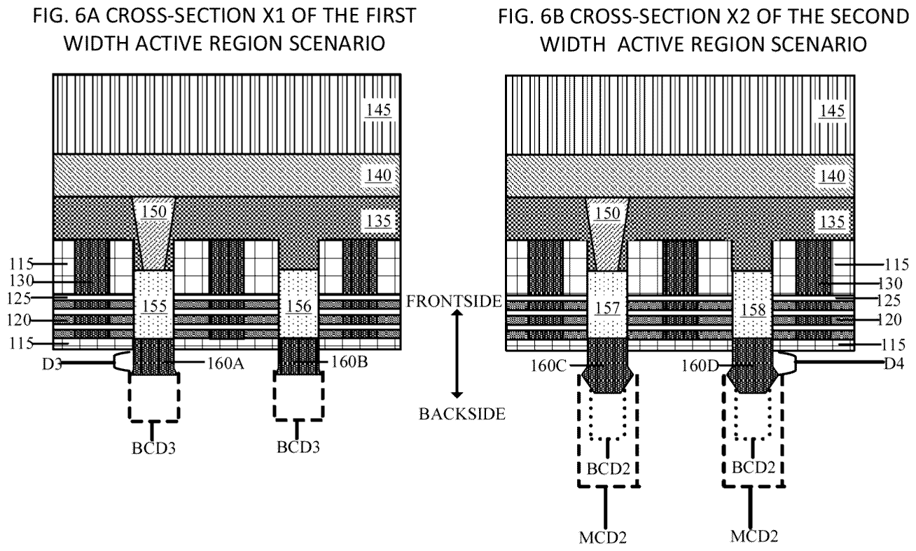

FIG. 5A illustrates the cross-section X1 of the first width active region scenario of the microelectronic structure after removal of the exposed bottom portion of the placeholders 160A and 160B and a portion of the unexposed portion of the placeholders 160A and 160B. The removal of the exposed portion and unexposed portion of the placeholders 160A and 160B may be performed using one or more removal/etching techniques, such as, suitable dry or wet etching, Reactive-ion etching (REI), or other suitable etching means to selectively target the exposed portion and a portion of the unexposed placeholders 160A and 160B as emphasized by dashed shapes 202A and 202B. The etching/removal of the exposed portion and unexposed portion of the placeholders 160A and 160B alters the dimensions of the placeholders 160A and 160B previously detailed at FIG. 3A. As will be illustrated in more detail in FIGS. 6A and 6B the BCD of placeholders 160A and 160B is now a similar width in comparison to the MCD of placeholders 160C and 160D.

FIG. 5B illustrates the cross-section X2 of the second width active region scenario of the microelectronic structure in the same state of the backside processing as FIG. 4B, after the removal of the etch stop layer 110 and partial etching of the second substrate 112.

FIG. 6A illustrates the cross-section X1 of the first width active region scenario of the microelectronic structure after the removal of the remaining second substrate 112 exposing the placeholders 160A and 160B in the ideal width active region scenario.

FIG. 6A further illustrates the new depth D3 of placeholders 160A and 160B resulting from the removal of the exposed portion and unexposed portion of the placeholders 160A and 160B at FIG. 5A. The new depth D3 is shallower than the original depth D1 of placeholders 160A and 160B. Additionally, FIG. 6A illustrates the new bottom critical dimension of placeholders 160A and 160B as emphasized by brackets BCD3. The width of the BCD of placeholders 160A and 160B is now greater than or equal to the width of the MCD and TCD of placeholders 160A and 160B. In contrast to FIG. 3A which illustrated placeholders 160A and 160B with a MCD greater than the BCD and TCD.

FIG. 6B illustrates the cross-section X2 of the second width active region scenario of the microelectronic structure after the removal of the remaining second substrate 112 exposing the placeholders 160C and 160D.

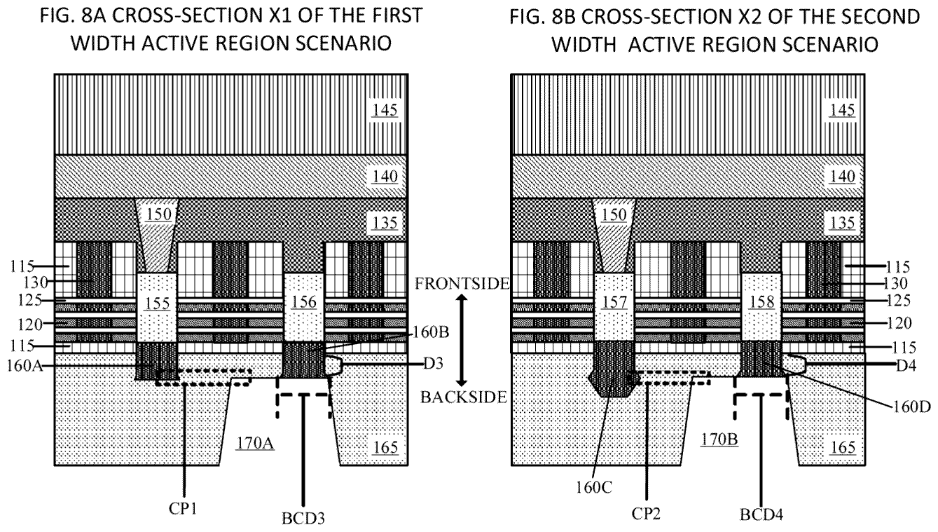

FIG. 6B illustrates the MCD depth D4 of the placeholders 160C and 160D. The MCD depth D4 of the placeholders 160C and 160D is substantially similar to the BCD depth and/or new depth D3 of placeholders 160A and 160B. Accordingly, the MCD of the placeholders 160C and 160D is substantially co-planar with the BCD of placeholders 160A and 160B, this will be illustrated in further detail in FIGS. 8A and 8B.

FIG. 6B further illustrates the BCD width and MCD width of placeholders 160C and 160D, emphasized using brackets BCD2 and MCD2. The MCD width of placeholders 160C and 160D, emphasized using brackets MCD2, is substantially similar to the BCD width of placeholders 160A and 160B, emphasized using brackets BCD3.

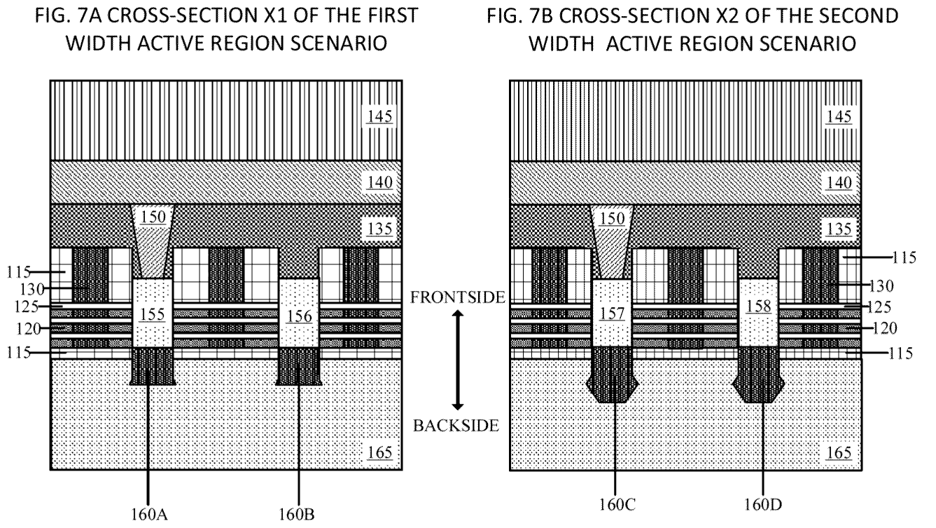

FIG. 7A illustrates the cross-section X1 of the first width active region scenario of the microelectronic structure after the formation of the backside interlayer dielectric layer 165. The backside interlayer dielectric layer 165 is formed on the backside of the bottom dielectric isolation layer 115 and surrounds the exposed portion of placeholders 160A and 160B.

FIG. 7B illustrates the cross-section X2 of the second width active region scenario of the microelectronic structure after the formation of the backside interlayer dielectric layer 165. The backside interlayer dielectric layer 165 is formed on the backside of the bottom dielectric isolation layer 115 and surrounds the exposed portion of placeholders 160C and 160D.

FIG. 8A illustrates the cross-section X1 of the first width active region scenario of the microelectronic structure after patterning of the backside interlayer dielectric layer 165 forming to form a backside contact trench 170A in contact with a backside surface of one of the placeholders 160B. Although the depth of the backside contact trench 170A is substantially similar to the depth of the placeholder 160B, as emphasized by bracket D3, that depth of the backside contact trench 170A and depth of the placeholder 160B may vary in other embodiments. The width of the backside contact trench 170A is greater than the width of the BCD of the placeholder 160B, emphasized using brackets BCD3, and extends beyond the BCD of placeholder 160B towards the placeholder 160A. The backside contact trench 170A is substantially co-planar with the backside surface of the placeholder 160A, as emphasized by dashed box CP1. As will be described in greater detail at FIG. 8B, the backside contact trench 170A in the first width active region scenario is substantially co-planar to the MCD of placeholder 160C.

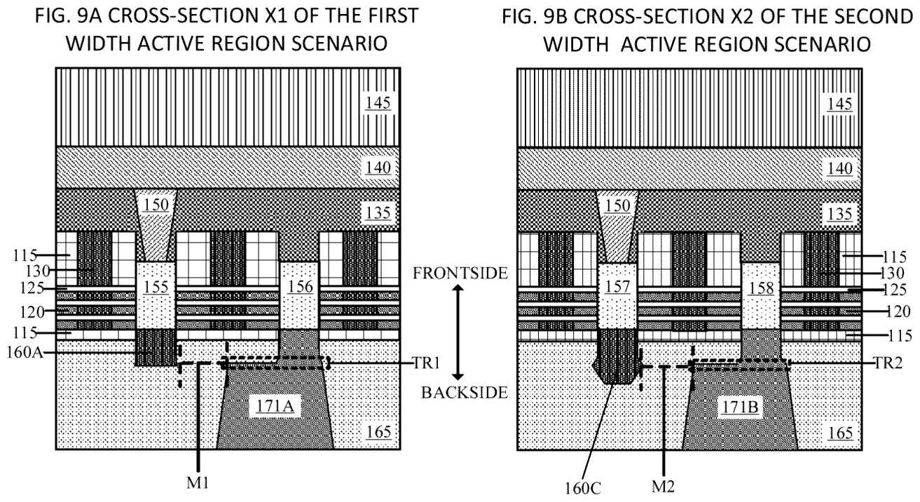

FIG. 8B illustrates the cross-section X2 of the second width active region scenario of the microelectronic structure after patterning of the backside interlayer dielectric layer 165 and removing a portion of one of the placeholders 160D such that a backside contact trench 170B is formed in contact with a backside surface of one of the placeholders 160D. The portion of the placeholder 160D that is removed results in a new BCD depth of the placeholder 160D which is a similar depth to the MCD of placeholder 160C. The portion of the placeholder 160D which is removed at this point in the process is clearly depicted when comparing FIG. 7B to FIG. 8B. Although the depth of the backside contact trench 170B is substantially similar to the depth of the MCD of the placeholder 160C, as emphasized by bracket D4, the depth of the backside contact trench 170B and depth MCD of placeholder 160C may vary in other embodiments. This results in the BCD of placeholder 160D, and the depth of the backside contact trench 170B being substantially co-planar with the MCD of placeholder 160C, as emphasized by dashed box CP1. The width of the backside contact trench 170B is greater than the width of the BCD of placeholder 160D, emphasized by brackets BCD4, and extends beyond the BCD of placeholder 160D towards the placeholder 160C. As described above at FIG. 8A, the backside contact trench 170A and the backside contact trench 170B are of similar depths, as emphasized by brackets D3 and D4. Additionally, the backside contact trenches 170A and 170B are of similar widths, which as will be explained in greater detail at FIGS. 9A and 9B, enables a safe margin between the placeholders 160A and 160C and the backside contacts.

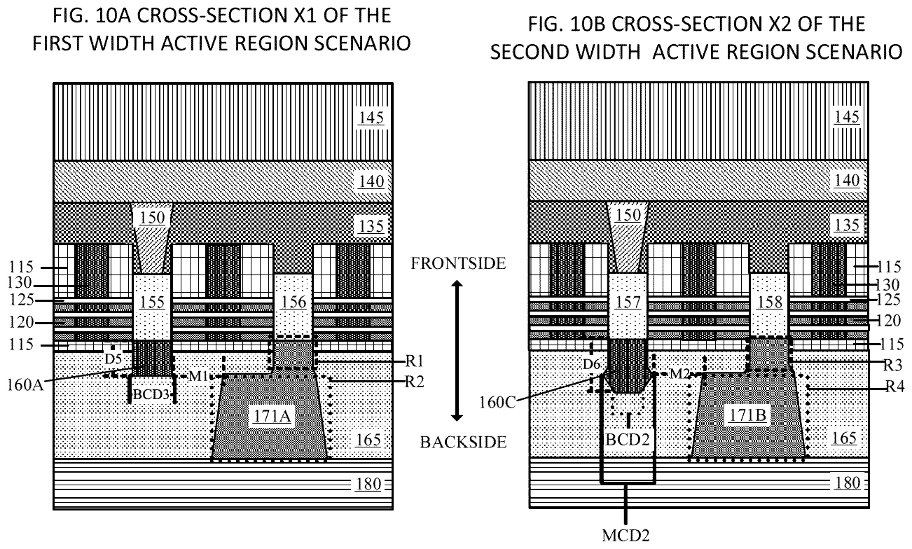

As will be described in greater detail below at FIGS. 9A and 10A, the formation of the backside contact through the metallization of the backside contact trenches 170A and 170B occurs in multiple stages. At a first stage, the transition region of backside contact trenches 170A and 170B is substantially co-planar with the BCD of the placeholder 160A and the MCD of the placeholder 160C.

FIG. 9A illustrates the cross-section X1 of the first width active region scenario of the microelectronic structure after the removal of the remaining portion of the placeholder 160B and the formation of the backside contact 171A with the backside surface of source/drain 156. The margin between the placeholder 160A and the backside contact 171A is emphasized by the dashed bracket M1.

FIG. 9A further illustrates the microelectronic structure after metallization of the backside contact 171A. The remaining portion of the placeholder 160B was etched using a suitable dry or wet etch to selectively target the placeholder 160B, or other suitable means to expand backside contact trench 170A illustrated in FIG. 8A. The backside contact trench 170A, including the removal of the remaining portion of the placeholder 160B is filled with a conductive material to form the backside contact 171A with the backside surface of the source/drain 156. The backside contact 171A includes a first region R1 and a second region R2 (see FIG. 10A). In-between the first region R1 and the second region R2 of the backside contact 171A is a first transition region TR1. The first transition region TR1 of the backside contact is substantially co-planar with backside-most portion or the bottom critical dimension of the first placeholder 160A.

FIG. 9B illustrates the cross-section X2 of the second width active region scenario of the microelectronic structure after the removal of the remaining portion of the placeholder 160D and the formation of the backside contact 171B with the backside surface of source/drain 158. The margin between the placeholder 160C and the backside contact 171B is emphasized by the dashed bracket M2. The width of margin M1, between the placeholder 160A and the backside contact 171A, can be the same, less than, or greater than the width of margin M2, between the placeholder 160C and the backside contact 171B. The backside contact 171B includes a third region R3 and a fourth region R4 (see FIG. 10B). In-between the third region R3 and the fourth region R4 of the backside contact 171B is a second transition region TR2. The second transition region TR2 of the backside contact 171B is substantially co-planar with a middle portion of the head region or middle critical dimension of the placeholder 160C.

FIG. 9B further illustrates the microelectronic structure after metallization of the backside contact 171B. The remaining portion of the placeholder 160D was etched using a suitable dry or wet etch to selectively target the placeholder 160D, or other suitable means to expand backside contact trench 170B illustrated in FIG. 8B. The backside contact trench 170B, including the removal of the remaining portion of the placeholder 160D is filled with a conductive material to form the backside contact 171B with the backside surface of the source/drain 158.

FIG. 10A illustrates the cross-section X1 of the first width active region scenario of the microelectronic structure after the formation of an additional backside interconnect 180. The backside interconnect 180 is formed on the backside of the backside interlayer dielectric layer 165 and the backside of the backside contact 171A.

The backside contact 171A includes two different regions, a first region, emphasized by dashed box R1, and a second region, emphasized by dashed box R2. In this embodiment, the first region R1 has a depth and shape similar to the depth D5 and shape of placeholder 160A, but the depth and shape may or may not be similar in other embodiments depending on variations in the fabrication process, such as, but not limited to etching techniques used. The second region R2 extends to the backside interconnect 180 and is wider than the first region R1. The margin between the backside contact 171A and the placeholder 160A is emphasized by bracket M1. As will be described in additional detail at FIG. 10B, the margin M1 between the backside contact 171A and the placeholder 160A can be the same, less, or greater than the margin M2 between the backside contact 171B and the placeholder 160C. The bottom critical dimension (BCD) of placeholder 160A, BCD3, is also substantially co-planar to the backside-most portion of the first region R1 and the frontside-most portion of the second region R2 of the backside contact 171A (e.g., first transition region TR1 illustrated in FIG. 9A) and the middle critical dimension (MCD) of placeholder 160C. The backside-most portion of the first region R1 and the frontside-most portion of the second region R2 of the backside contact 171A may also be referred to as the transition region of the backside contact 171A, which is emphasized by dashed box TR1 in FIG. 9A.

The depth and shape of placeholder 160A are different from the depth and shape of placeholder 160C. The depth of placeholder 160A, emphasized by dashed bracket D5 is less than the depth of placeholder 160C, which is emphasized by dashed bracket D6. Additionally, while the placeholder 160A has a bottom critical dimension (BCD) slightly wider than its middle critical dimension (MCD) and top critical dimension (TCD), placeholder 160C has a shaft and head region. Placeholder 160A previously included a shaft and head region, see FIGS. 2-4, but head region was selectively removed/etched during the fabrication process, as illustrated at FIG. 5A. The shaft region of placeholder 160C includes a width equal to the top critical dimension (TCD) and the head region including both the middle critical dimension (MCD) and bottom critical dimension (BCD) which is described above in greater detail in FIG. 3A. The BCD of placeholder 160A, BCD3, may be of greater width or similar or equal width to the MCD of placeholder 160C, MCD2.

FIG. 10B illustrates the cross-section X2 of the second width active region scenario of the microelectronic structure after the formation of an additional backside interconnect 180. The backside interconnect 180 is formed on the backside of the backside interlayer dielectric layer 165 and the backside of the backside contact 171B.

The backside contact 171B includes two different regions, a third region, emphasized by dashed box R3, and a fourth region, emphasized by dashed box R4. The third region R3 has a depth substantially co-planar with the middle of the head region or middle critical dimension of placeholder 160C. The fourth region R4 extends to the backside interconnect 180 and is wider than the third region R3. The margin between the backside contact 171B and the placeholder 160C is emphasized by bracket M2. The margin M2 between the backside contact 171B and the placeholder 160C can be the same, less, or greater than the margin M1 between the backside contact 171A and the placeholder 160A of FIG. 10A. The middle critical dimension (MCD) of placeholder 160C, MCD2, is also substantially co-planar to the backside-most portion of the third region R3 and the frontside-most portion of the fourth region R4 of the backside contact 171B (e.g., second transition region TR2 illustrated in FIG. 9B). The backside-most portion of the third region R3 and the frontside-most portion of the fourth region R4 of the backside contact 171B may also be referred to as the second transition region TR2 of the backside contact 171B, which is emphasized by dashed box TR2 in FIG. 9B.

The depth and shape of placeholder 160C are different from the depth and shape of placeholder 160A. The depth of placeholder 160C, emphasized by dashed bracket D6 is greater than the depth of placeholder 160A, which is emphasized by dashed bracket D5. Placeholder 160C has a shaft and head region the largest width of the head region includes by the middle critical dimension MCD2 and the bottom critical dimension BCD2 while the shaft region includes the top critical dimension.

While the figures only illustrate two different widths for the active region this is not meant to be seen as limiting to the present invention. The cross-sections that extend through the active region of the microelectronic structure and that are perpendicular to the gate direction may be of varying widths. Additionally, while the figures only illustrate two different shapes and depths of the placeholders this is not meant to be seen as limiting. The invention is applicable to various additional shapes and depths of the placeholders resulting from variations in the fabrication process. For example, although the depth of the backside contact trench 170A is substantially similar to the depth of the placeholder 160B, as emphasized by bracket D3, that depth of the backside contact trench 170A and depth of the placeholder 160B may vary in other embodiments and although the depth of the backside contact trench 170B is substantially similar to the depth of the MCD of the placeholder 160C, as emphasized by bracket D4, the depth of the backside contact trench 170B and depth MCD of placeholder 160C may vary in other embodiments.

A microelectronic structure that includes a first nanosheet FET. The first nanosheet FET has an active region having a first width X1, the first width X1 is measured in parallel with a gate direction. The first nanosheet FET includes a first placeholder 160A, and a first source/drain 155. The first placeholder 160A is located on a backside of the first source/drain 155. The first placeholder 160A has a first depth D5, the first depth D5 is measured from the backside of the first source/drain 155 towards the backside of the first nanosheet FET. A second nanosheet FET, the second nanosheet FET has an active region having a second width X2. The second width X2 is measured in parallel with the gate direction, the second width X2 is smaller than the first width X1. The second nanosheet FET includes a second placeholder 160C, and a second source/drain 157, the second placeholder is located on a backside of the second source/drain 157. The second placeholder 160C has a second depth D6, the second depth D6 is measured from the backside of the second source/drain 157 towards the backside of the second nanosheet FET.

The first active region width X1 of the first nanosheet FET is greater than 15 nanometers. The second active region width X2 of the second nanosheet FET is less than or equal to 15 nanometers.

The first depth D5 of the first placeholder 160A is different from the second depth D6 of the second placeholder 160C.

The shape for each of the first placeholder 160A and the second placeholder 160C are different when viewed from a vertical cross-section perspective that is perpendicular to the gate direction. The shape of the first placeholder 160A has a rectangular shape that extends horizontally outwards in both directions at a backside-most portion of the rectangular shape when viewed from the vertical cross-section perspective that is perpendicular to the gate direction. The shape of the second placeholder 160C has a head and a shaft region when viewed from the vertical cross-section perspective that is perpendicular to the gate direction.

The width of a bottom critical dimension BCD3 of the first placeholder 160A is substantially equal to a width of a middle critical dimension MCD2 of the second placeholder 160C when viewed from the vertical cross-section perspective that is perpendicular to the gate direction.

A microelectronic structure that includes a first nanosheet FET. The first nanosheet FET has an active region having a first width X1, the first width X1 is measured in parallel with a gate direction. The first nanosheet FET also includes a first placeholder 160A, a first backside contact 171A, a first source/drain 155, and a second source/drain 156. The first placeholder 160A is located on a backside of the first source/drain 155 and the first placeholder 160A has a first depth D5. The first depth D5 is measured from the backside of the first source/drain 155 towards the backside of the first nanosheet FET. The first backside contact 171A is located on a backside of the second source/drain 156. A second nanosheet FET, the second nanosheet FET has an active region having a second width X2, the second width X2 is measured in parallel with the gate direction. The second width X2 is smaller than the first width X1. The second nanosheet FET includes a second placeholder 160C, a second backside contact 171B, a third source/drain 157, and a fourth source/drain 158. The second placeholder 160C is located on a backside of the third source/drain 157 and the second placeholder 160C has a second depth D6, the second depth D6 is measured from the backside of the third source/drain 157 towards the backside of the second nanosheet FET. The second backside contact 171B is located on a backside of the fourth source/drain 158.

The first active region width X1 of the first nanosheet FET is greater than 15 nanometers, and the second active region width X2 of the second nanosheet FET is less than or equal to 15 nanometers.

The value for the first depth D5 of the first placeholder 160A is less than a value for the second depth D6 of the second placeholder 160C.

The shape for each of the first placeholder 160A and the second placeholder 160C are different when viewed from a vertical cross-section perspective that is perpendicular to the gate direction. The shape of the first placeholder 160A has a rectangular shape that extends horizontally outwards in both directions at a backside-most portion of the rectangular shape. The shape of the second placeholder 160C has a head and a shaft region when viewed from the vertical cross-section perspective that is perpendicular to the gate direction.

The width of a bottom critical dimension BCD3 of the first placeholder 160A is substantially equal to a width of a middle critical dimension MCD2 of the second placeholder 160C when viewed from the vertical cross-section perspective that is perpendicular to the gate direction.

The first backside contact 171A includes a first region R1 and a second region R2, the first region R1 is located on the backside of the second source/drain 156 and the second region R2 is connected to a backside portion of the first region R1 and extends downwards to a frontside of a backside interconnect 180.

The second backside contact 171B includes a third region R3 and a fourth region R4, the third region R3 is located on the backside of the fourth source/drain 158 and the fourth region R4 is connected to a backside portion of the third region R3 and extends downwards to a frontside of a second backside interconnect 180.

The first region R1 of the first backside contact 171A has a narrower width than the second region R2, and the third region R3 of the second backside contact 171B has a narrower width than the fourth region R4 when viewed from the vertical cross-section perspective that is perpendicular to the gate direction.

The first backside contact 171A includes a first transition region TR1 in-between the first region R1 and the second region R2. The second backside contact 171B includes a second transition region TR2 in-between the third region R3 and the fourth region R4.

The first nanosheet FET also includes a first margin M1 in-between a backside of first placeholder 160A and the first transition region TR1 of the first backside contact 171A. The second nanosheet FET also includes a second margin M2 in-between a middle portion of a head region of the second placeholder 160C and the second transition region TR2 of the second backside contact 171B. The width of the first margin M1 can be the same, less, or greater than a width of the second margin M2.

A method comprising forming a first nanosheet FET. The formation of the first nanosheet FET includes forming an active region having a first width X1, the first width X1 is measured in parallel with a gate direction. The first nanosheet FET includes a first placeholder 160A, and a first source/drain 155. The first placeholder 160A is located on a backside of the first source/drain 155. The first placeholder 160A has a first depth D5, the first depth D5 is measured from the backside of the first source/drain 155 towards the backside of the first nanosheet FET. The further comprises forming a second nanosheet FET. The formation of the second nanosheet includes forming an active region having a second width X2. The second width X2 is measured in parallel with the gate direction, the second width X2 is smaller than the first width X1. The second nanosheet FET includes a second placeholder 160C, and a second source/drain 157, the second placeholder is located on a backside of the second source/drain 157. The second placeholder 160C has a second depth D6, the second depth D6 is measured from the backside of the second source/drain 157 towards the backside of the second nanosheet FET.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet FET, wherein the first nanosheet FET has an active region having a first width, wherein the first width is measured in parallel with a gate direction, wherein the first nanosheet FET includes a first placeholder, and a first source/drain, wherein first placeholder is located on a backside of the first source/drain, wherein the first placeholder has a first depth, wherein the first depth as measured from the backside of the first source/drain towards the backside of the first nanosheet FET; and
a second nanosheet FET, wherein the second nanosheet FET has an active region having a second width, wherein the second width is measured in parallel with the gate direction, wherein the second width is smaller than the first width, wherein the second nanosheet FET includes a second placeholder, and a second source/drain, wherein second placeholder is located on a backside of the second source/drain, wherein the second placeholder has a second depth, wherein the second depth as measured from the backside of the second source/drain towards the backside of the second nanosheet FET.

2. The microelectronic structure of claim 1, wherein the first active region width of the first nanosheet FET is greater than 15 nanometers.

3. The microelectronic structure of claim 1, wherein the second active region width of the second nanosheet FET is less than or equal to 15 nanometers.

4. The microelectronic structure of claim 1, wherein a value for each of the first depth and the second depth are different.

5. The microelectronic structure of claim 1, wherein a shape for each of the first placeholder and the second placeholder are different when viewed from a vertical cross-section perspective that is perpendicular to the gate direction.

6. The microelectronic structure of claim 5, wherein the shape of the first placeholder has a rectangular shape that extends horizontally outwards in both directions at a backside-most portion of the rectangular shape when viewed from the vertical cross-section perspective that is perpendicular to the gate direction.

7. The microelectronic structure of claim 6, wherein the shape of the second placeholder has a head and a shaft region when viewed from the vertical cross-section perspective that is perpendicular to the gate direction.

8. The microelectronic structure of claim 5, wherein a width of a bottom critical dimension of the first placeholder is substantially equal to a width of a middle critical dimension of the second placeholder when viewed from the vertical cross-section perspective that is perpendicular to the gate direction.

9. A microelectronic structure comprising:
a first nanosheet FET, wherein the first nanosheet FET has an active region having a first width, wherein the first width is measured in parallel with a gate direction, wherein the first nanosheet FET includes a first placeholder, a first backside contact, a first source/drain, and a second source/drain, wherein first placeholder is located on a backside of the first source/drain, wherein the first placeholder has a first depth, wherein the first depth as measured from the backside of the first source/drain towards the backside of the first nanosheet FET, and wherein the first backside contact is located on a backside of the second source/drain; and
a second nanosheet FET, wherein the second nanosheet FET has an active region having a second width, wherein the second width is measured in parallel with the gate direction, wherein the second width is smaller than the first width, wherein the second nanosheet FET includes a second placeholder, a second backside contact, a third source/drain, and a fourth source/drain, wherein second placeholder is located on a backside of the third source/drain, wherein the second placeholder has a second depth, wherein the second depth as measured from the backside of the third source/drain towards the backside of the second nanosheet FET, and wherein the second backside contact is located on a backside of the fourth source/drain.

10. The microelectronic structure of claim 9, wherein the first active region width of the first nanosheet FET is greater than 15 nanometers, and wherein the second active region width of the second nanosheet FET is less than or equal to 15 nanometers.

11. The microelectronic structure of claim 9, wherein a value for the first depth of the first placeholder is less than a value for the second depth of the second placeholder.

12. The microelectronic structure of claim 9, wherein a shape for each of the first placeholder and the second placeholder are different when viewed from a vertical cross-section perspective that is perpendicular to the gate direction, wherein the shape of the first placeholder has a rectangular shape that extends horizontally outwards in both directions at a backside-most portion of the rectangular shape, and wherein the shape of the second placeholder has a head and a shaft region when viewed from the vertical cross-section perspective that is perpendicular to the gate direction.

13. The microelectronic structure of claim 12, wherein a width of a bottom critical dimension of the first placeholder is substantially equal to a width of a middle critical dimension of the second placeholder when viewed from the vertical cross-section perspective that is perpendicular to the gate direction.

14. The microelectronic structure of claim 9, wherein the first backside contact includes a first region and a second region, the first region is located on the backside of the second source/drain and the second region is connected to a backside portion of the first region and extends downwards to a frontside of a backside interconnect.

15. The microelectronic structure of claim 14, wherein the second backside contact includes a third region and a fourth region, the third region is located on the backside of the fourth source/drain and the fourth region is connected to a backside portion of the third region and extends downwards to a frontside of a second backside interconnect.

16. The microelectronic structure of claim 15, wherein the first region has a narrower width than the second region, and the third region has a narrower width than the fourth region when viewed from the vertical cross-section perspective that is perpendicular to the gate direction.

17. The microelectronic structure of claim 15, wherein the first backside contact includes a first transition region in-between the first region and the second region, and wherein the second backside contact includes a second transition region in-between the third region and the fourth region.

18. The microelectronic structure of claim 17, further comprising:
a first margin between a backside of first placeholder and the first transition region of the first backside contact; and
a second margin between a middle portion of a head region of the second placeholder and the second transition region of the second backside contact.

19. The microelectronic structure of claim 18, wherein a width of the first margin can be the same, less, or greater than a width of the second margin.

20. A method comprising:
forming a first nanosheet FET, wherein the first nanosheet FET has an active region having a first width, wherein the first width is measured in parallel with a gate direction, wherein the first nanosheet FET includes a first placeholder, and a first source/drain, wherein first placeholder is located on a backside of the first source/drain, wherein the first placeholder has a first depth, wherein the first depth as measured from the backside of the first source/drain towards the backside of the first nanosheet FET; and
forming a second nanosheet FET, wherein the second nanosheet FET has an active region having a second width, wherein the second width is measured in parallel with the gate direction, wherein the second width is smaller than the first width, wherein the second nanosheet FET includes a second placeholder, and a second source/drain, wherein second placeholder is located on a backside of the second source/drain, wherein the second placeholder has a second depth, wherein the second depth as measured from the backside of the second source/drain towards the backside of the second nanosheet FET.
